(19) United States
(12) Patent Application Publication
(10) Pub. No.: US 2016/0126697 A1
(43) Pub. Date: May 5, 2016

(54) SEMICONDUCTOR LASER DEVICE AND METHOD FOR PRODUCING SAME

(71) Applicant: SHARP KABUSHIKI KAISHA, Osaka-shi (JP)

(72) Inventor: Kazuhiro TSUCHIDA, Osaka-shi (JP)

(73) Assignee: SHARP KABUSHIKI KAISHA, Osaka-shi (JP)

(21) Appl. No.: 14/892,379

(22) PCT Filed: Aug. 21, 2014
(86) PCT No.: PCT/JP2014/071828

§ 371 Date: Nov. 19, 2015

(30) Foreign Application Priority Data
Oct. 7, 2013 (JP) 2013-210163

(51) Int. Cl. H01S 5/022

(52) U.S. Cl. CPC H01S 5/02288; H01S 5/02244

(57) ABSTRACT

In a semiconductor laser device including a semiconductor laser element that emits laser light from an emission region thereof, a cap having a peripheral wall and a ceiling wall that cover the semiconductor laser element and having a window portion formed in the ceiling wall to face the emission region, and a transparent optical member that fills the window portion, the optical member is formed by curing a liquid resin and holds the ceiling wall, and a light incidence surface of the optical member faces the emission region and is formed by natural flow of the liquid resin.

### CROSS REFERENCE TO RELATED APPLICATIONS

This application is a U.S. National Phase patent application of PCT/JP2014/071828, filed on Aug. 21, 2014, which claims priority to Japanese Application No. 2013-210163, filed on Oct. 7, 2013, each of which is hereby incorporated by reference in the present disclosure in its entirety.

### FIELD OF THE INVENTION

The present invention relates to a semiconductor laser device including an optical member such as a lens, and a method for producing the same.

### BACKGROUND OF THE INVENTION

FIG. 15 shows a front sectional view of a conventional semiconductor laser device. A semiconductor laser device 1 is configured such that a semiconductor laser element 4 that emits laser light from an emission region 4a thereof is fixed on a stem 2 via a submount 3. On the stem 2, there is provided a metal cap 5 that covers the semiconductor laser element 4.

The cap 5 is formed in a bottomed cylinder shape having a peripheral wall 5a and a ceiling wall 5b, and a flange portion 5d projecting outward from a lower edge of the peripheral wall 5a is fixed to the stem 2. In the ceiling wall 5b, there is formed a window portion 5c facing the emission region 4a of the semiconductor laser element 4.

The ceiling wall 5b of the cap 5 is provided with a transparent optical member 6 that fills up the window portion Sc. Thereby, an inside of the cap 5 is hermetically sealed. The optical member 6 has a curved light emission surface 6a and forms a lens.

Laser light emitted from the emission region 4a of the semiconductor laser element 4 enters the optical member 6 through the window portion 5c, and then the laser light is converged and emitted from the light emission surface 6a of the optical member 6.

In the semiconductor laser device 1, when used for optical communications and the like, the optical member 6 is typically formed of glass which has a small lens aberration. In recent years, thanks to higher-powered semiconductor laser devices that emit infrared rays, higher-performance photo sensors, or faster operational circuits, infrared laser has been becoming to be used in an increasingly wider range. For example, there have been rapidly increasing demands for infrared laser as a light source for sensors to be used in three-dimensional measurement.

When used as the light source of such a sensor and the like, laser light is sometimes made to scatter to illuminate a wide range, and in such a case, the aberration of a lens does not cause much inconvenience. Thus, by forming the optical member 6 of the semiconductor laser device 1 of an epoxy resin or a silicone resin, which is low-cost and easy to be worked, it is possible to reduce cost of the semiconductor laser device 1. This may help promote further spread of the semiconductor laser device 1 employing the optical member 6 made of resin.

There is also a case where, in view of safety for eyes, the optical member 6 is provided for the purpose of scattering laser light to enlarge an apparent light source (a virtual light source) so as to reduce energy concentration on a retina. In such a case, if the optical member 6 is formed of a silicone resin, adhesive strength of the optical member 6 with respect to the metal cap 5 is weak, and thus the optical member 6 may be caused to come off by an external force F and the like as shown in FIG. 16. If this happens, laser light emitted from the emission region 4a is discharged directly into the air through the window portion 5c as indicated by arrow E, and this would disadvantageously make the semiconductor laser device 1 less safe.

Further, if the optical member 6 is formed of an epoxy resin, the optical member 6 has a high adhesive strength with respect to the metal cap 5. However, there is a case where, if the semiconductor laser device 1 is exposed to high temperature through, for example, reflow soldering after a high-humidity/high-temperature examination, the optical member 6 comes off from the cap 5 at an interface with respect to the cap 5. Thus, like in the above case, the semiconductor laser device 1 is disadvantageously made less safe.

Patent Literatures 1 and 2 each disclose a semiconductor laser device 1 capable of preventing an optical member 6 from coming off from a cap 5. A feature disclosed in Patent Literature 1 is such that glass as a base material of an optical member 6 and a cap 5 placed in a space between upper and lower mold members of a mold are melt by applying heat. As a result, the optical member 6, which is convex toward both sides, holds a ceiling wall 5b via a window portion 5c, and thereby, the optical member 6 is prevented from coming off. Also in a case where the optical member 6 is made of resin, it is possible to form the optical member 6 by means of a similar mold.

A feature disclosed in Patent Literature 2 is such that an optical member 6 convex toward both sides and a cap 5 are integrally formed by injection molding where resin is forced into a space between upper and lower mold members of a mold. Thereby, it is possible to prevent the optical member 6 from coming off.

[Patent Literature 1] JP-A-2006-301352 (pages 4 to 7, FIG. 2, FIG. 3)

[Patent Literature 2] JP-A-H09-205251 (pages 3 to 5, FIG. 3)

[Patent Literature 3] JP-A-559-218430 (pages 1 and 2, FIG. 1, FIG. 4)

### SUMMARY OF THE INVENTION

However, according to the semiconductor laser devices 1 disclosed in Patent Literatures 1 and 2 which have been described above, since the optical member 6 is formed by means of a mold having upper and lower mold members, a complicated molding apparatus is required. This has caused a problem of increased cost of the semiconductor laser device 1 including the optical member 6.

An object of the present invention is to provide a semiconductor laser device capable of improving safety and reducing cost, and a method for producing such a semiconductor laser device.

To achieve the above object, according to an aspect of the present invention, a semiconductor laser device includes a semiconductor laser element that emits laser light from an emission region thereof, a cap having a peripheral wall and a ceiling wall that cover the semiconductor laser element and having a window portion formed in the ceiling wall to face the emission region, and a transparent optical member that fills the window portion. Here, the optical member is formed by curing a liquid resin and holds the ceiling wall, and a light incidence surface of the optical member faces the emission region and is formed by natural flow of the liquid resin.

According to the present invention, in the semiconductor laser device configured as described above, the optical member is preferably formed of one of a thermosetting resin or an ultraviolet setting resin.

According to the present invention, in the semiconductor laser device configured as described above, the optical member preferably contains a scattering material.

According to the present invention, in the semiconductor laser device configured as described above, the optical member preferably has an extension portion extending continuously from over the ceiling wall to over an outer surface of the peripheral wall and contacts an inner surface of the peripheral wall, such that the peripheral wall is held by the optical member.

According to another aspect of the present invention, in a method for producing a semiconductor laser device comprising a semiconductor laser element that emits laser light from an emission region thereof, a cap having a peripheral wall and a ceiling wall that cover the semiconductor laser element and having a window portion formed in the ceiling wall to face the emission region, and a transparent optical member that fills the window portion, a mold is provided including a concave portion for forming a light emission surface of the optical member, and an enlarged-diameter portion that is formed at an open end of the concave portion to have a larger diameter than the concave portion and in which the cap is to be fitted, a liquid resin is poured into the mold to fill the concave portion and to a height above a bottom surface of the enlarged-diameter portion, and thereafter, the cap is inserted into the enlarged-diameter portion with the ceiling wall facing downward and the liquid resin flows into the cap through the window portion and naturally flows on an inner surface of the ceiling wall, and then the liquid resin is cured, and thereby the optical member that holds the ceiling wall is formed.

According to the present invention, in the method for producing the semiconductor laser device configured as described above, the cap preferably has a flange portion projecting outward from an end portion thereof opposite to the ceiling wall, and a hanger member is preferably provided for supporting the flange portion in inserting and releasing the cap with respect to the enlarged-diameter portion.

According to the present invention, a transparent optical member that fills an opening formed in a cap holds a ceiling wall of the cap, and a light incidence surface of the optical member is formed by natural flow of a liquid resin. This makes it possible to prevent the optical member from coming off, and to form the optical member by means of a simple device. Thus, it is possible to achieve a safer and lower-cost semiconductor laser device.

According to the present invention, a liquid resin is poured into a mold to fill a concave portion and to a height above a bottom surface of an enlarged-diameter portion, and thereafter, a cap is inserted into the enlarged-diameter portion of the mold, so that the liquid resin flows into the cap through a window portion and naturally flows on an inner surface of a ceiling wall, and then the liquid resin is cured. Thereby, it is possible to easily form an optical member capable of being prevented from coming off from the cap. It is also possible to prevent an air layer or an air bubble from being generated when the optical member is formed. Thus, it is possible to achieve a safer and lower-cost semiconductor laser device.

### BRIEF DESCRIPTION OF THE DRAWINGS

FIG. 1 is a front sectional view showing a semiconductor laser device according to a first embodiment of the present invention;

FIG. 2 is a front sectional view showing a mold of an optical member of the semiconductor laser device according to the first embodiment of the present invention;

FIG. 3 is a front sectional view showing a state after a liquid resin is poured into the mold of the optical member of the semiconductor laser device according to the first embodiment of the present invention;

FIG. 4 is a front sectional view showing a state where a cap is placed in the mold of the optical member of the semiconductor laser device according to the first embodiment of the present invention;

FIG. 5 is a front sectional view showing a state in the curing of the optical member of the semiconductor laser device according to the first embodiment of the present invention;

FIG. 6 is a front sectional view showing a state where the liquid resin is being poured into the mold of the optical member of the semiconductor laser device according to the first embodiment of the present invention after the cap is placed in the mold;

FIG. 7 is a front sectional view showing a state where an air layer is formed after the liquid resin is poured into the mold of the optical member of the semiconductor laser device according to the first embodiment of the present invention after the cap is placed in the mold;

FIG. 8 is a front sectional view showing a state where an air pool is formed after the liquid resin is poured into the mold of the optical member of the semiconductor laser device according to the first embodiment of the present invention after the cap is placed in the mold;

FIG. 9 is a front sectional view showing a state where air bubbles are formed in the optical member of the semiconductor laser device according to the first embodiment of the present invention;

FIG. 10 is a front sectional view showing a state where an external force is applied to the optical member of the semiconductor laser device according to the first embodiment of the present invention;

FIG. 11 is a front sectional view showing a semiconductor laser device according to a second embodiment of the present invention;

FIG. 12 is a front sectional view showing a semiconductor laser device according to a third embodiment of the present invention;

FIG. 13 is a top view showing a mold of an optical member of the semiconductor laser device according to the third embodiment of the present invention;

FIG. 14 is a sectional view taken along line AOA of FIG. 13;

FIG. 15 is a front sectional view showing a conventional semiconductor laser device; and

FIG. 16 is a front sectional view showing a state where an external force is applied to an optical member of the conventional semiconductor laser device.

### DETAILED DESCRIPTION OF THE INVENTION

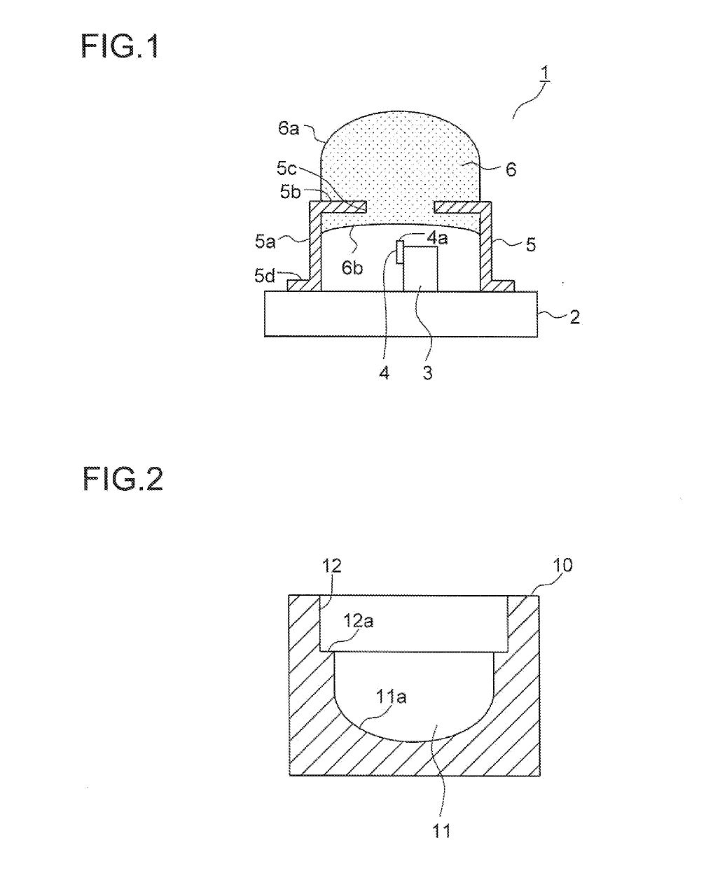

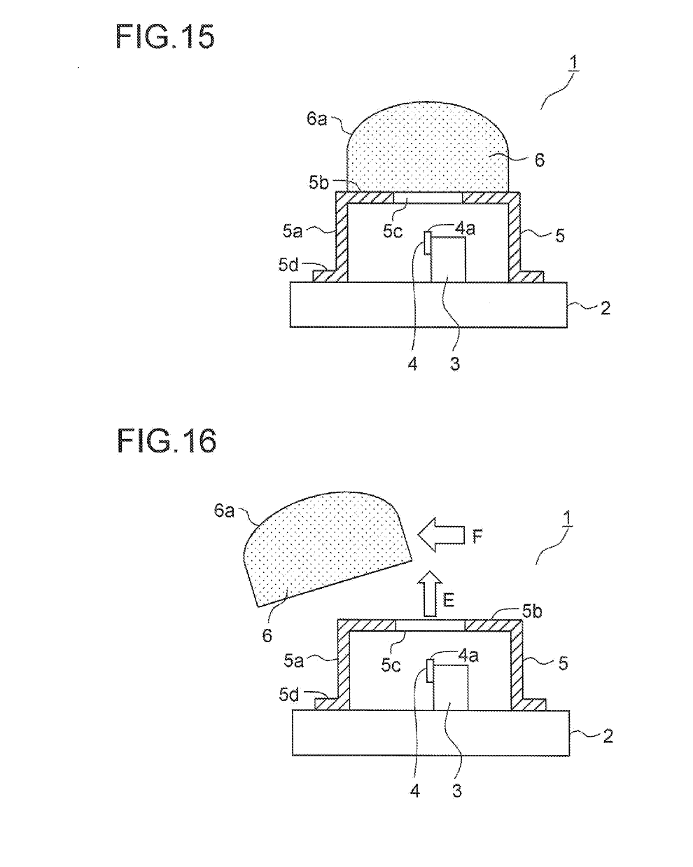

With reference to the accompanying drawings, embodiments of the present invention will be described below. FIG. 1 shows a front sectional view of a semiconductor laser device according to a first embodiment. For convenience of description, such portions as find their counterparts in the conventional example shown in FIG. 15 referred to above are denoted by common reference signs.

A semiconductor laser device 1 has a semiconductor laser element 4 that emits laser light such as infrared light from an emission region 4a thereof, and the semiconductor laser element 4 is fixed to a stem 2 via a submount 3. On the stem 2, there is provided a metal cap 5 that covers the semiconductor laser element 4. The cap 5 is formed in a bottomed cylinder shape having a peripheral wall 5a and a ceiling wall 5b. A flange portion 5d projects outward from a lower edge of the peripheral wall 5a, that is, an edge of the peripheral wall 5a opposite to the ceiling wall 5b, and the flange portion 5d is fixed to the stem 2. In the ceiling wall 5b, there is formed a window portion 5c to face the emission region 4a of the semiconductor laser element 4.

At the ceiling wall 5b of the cap 5, there is disposed a transparent optical member 6 that fills the window portion 5c. Thereby, an inside of the cap 5 is hermetically sealed. The optical member 6 holds the ceiling wall 5b via the window portion 5c, and forms a lens having a convex light emission surface 6a and a substantially flat light incidence surface 6b that faces the emission region 4a. The optical member 6 is formed of a thermosetting resin, and as will be later described in detail, the light incidence surface 6b is formed by natural flow of the thermosetting resin.

In the semiconductor laser device 1 configured as described above, laser light emitted from the emission region 4a of the semiconductor laser element 4 is incident on the optical member 6 through the light incidence surface 6b. The laser light that has entered the optical member 6 is converged and emitted from the light emission surface 6a of the optical member 6.

Since the optical member 6 is formed of a resin, it has a larger aberration and thus light emitted therefrom is scattered to a larger extent in comparison with a case where it is formed of glass. Thus, the semiconductor laser device 1 is put to use in, for example, a sensor light source that irradiates a large area with laser light. There, scattered laser light makes a large apparent light source, and this helps reduce concentration of energy on a retina.

Here, the optical member 6 may contain a scattering material such as silica. This makes it possible to scatter emitted light to a larger extent, and thus to further reduce concentration of energy on a retina.

FIG. 2 shows a front sectional view of a mold used for forming the optical member 6. A mold 10 is made of resin, for example, and has a concave portion 11 having an open top end face and an enlarged-diameter portion 12 formed over the open end of the concave portion 11 to have a larger diameter than the concave portion 11. The concave portion 11 has an inner surface 11a, according to whose shape the light emission surface 6a of the optical member 6 (see FIG. 1) is formed. The enlarged-diameter portion 12 is formed to have an inner diameter that allows the peripheral wall 5a of the cap 5 (see FIG. 1) to fit therein, and the cap 5 is to be inserted into the enlarged-diameter portion 12.

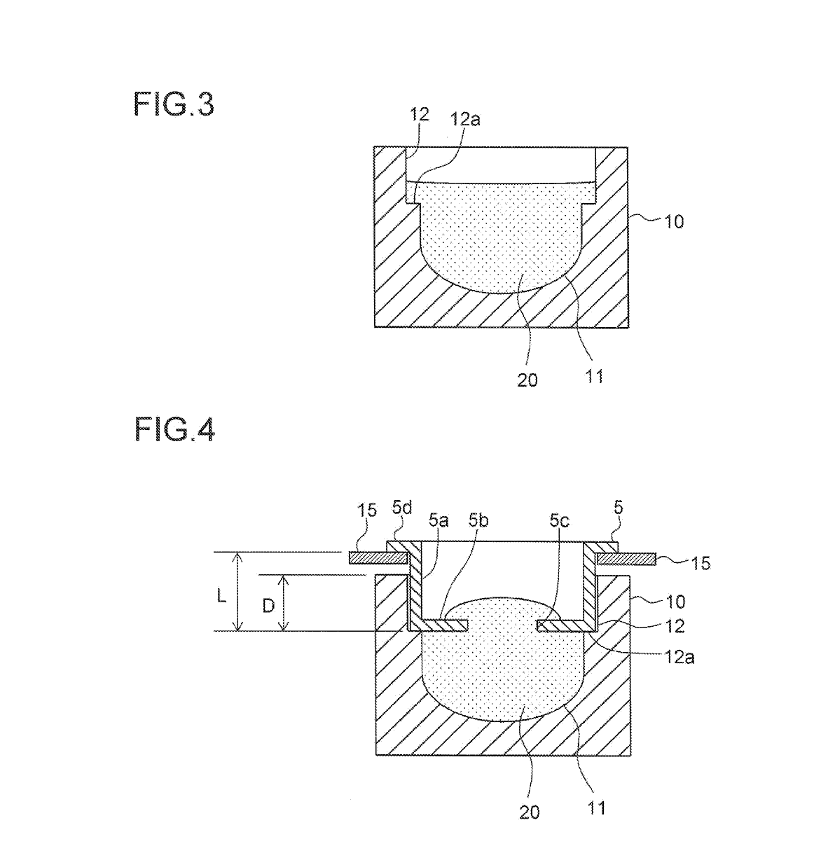

FIGS. 3 to 5 are front sectional views sequentially showing a process of forming the optical member 6 by using the mold 10. As shown in FIG. 3, a liquid resin 20 which is a thermosetting resin is poured into the mold 10 to fill the concave portion 11 and to a height above a bottom surface 12a of the enlarged-diameter portion 12.

Next, as shown in FIG. 4, the flange portion 5d of the cap 5 is supported by a hanger member 15, and the hanger member 15 is lowered to insert the cap 5 into the enlarged-diameter portion 12 with the ceiling wall 5b facing down. Thereby, the ceiling wall 5b of the cap 5 is placed on the bottom surface 12a of the enlarged-diameter portion 12 to be soaked in the liquid resin 20, and the liquid resin 20 reaches an inner surface of the ceiling wall 5b via the window portion 5c.

At this time, a distance L between an upper surface (which appears to be a lower surface in the figure) of the ceiling wall 5b of the cap 5 and an upper surface (which appears to be a lower surface in the figure) of the flange portion 5d is larger than a depth D of the enlarged-diameter portion 12. Thus, the hanger member 15 is able to be disposed in a gap between an upper surface of the mold 10 and the flange portion 5d, to make it possible to insert the cap 5 into the enlarged-diameter portion 12 easily.

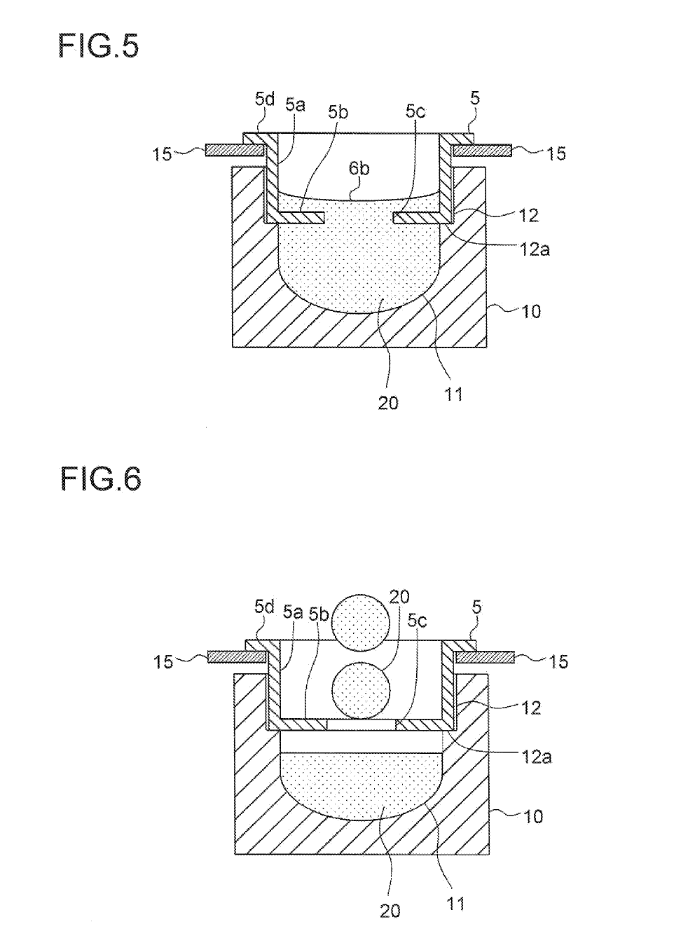

Next, as shown in FIG. 5, the liquid resin 20 naturally flows on the inner surface of the ceiling wall 5b and reaches an inner surface of the peripheral wall 5a. Thereafter, temperature of the mold 10 rises to cause the liquid resin 20 to cure, and thereby the resin optical member 6 (see FIG. 1) that holds the ceiling wall 5b is formed. Then, the hanger member 15 is raised to thereby take the optical member 6 out of the mold 10.

The light incidence surface 6b of the optical member 6 is formed by natural flow of the liquid resin 20, and the light incidence surface 6b is formed as a slightly concave but substantially flat surface due to, for example, surface tension of the liquid resin 20 and shrinking of the liquid resin 20 occurring when it cures. By adjusting curing conditions or viscosity of the liquid resin 20, or a volatile component of a curing agent, it is possible to form the light incidence surface 6b to have a desired curvature.

Thereby, it is possible to form the optical member 6 easily by means of a simple molding apparatus having the single mold 10, and thus to reduce cost of the semiconductor laser device 1.

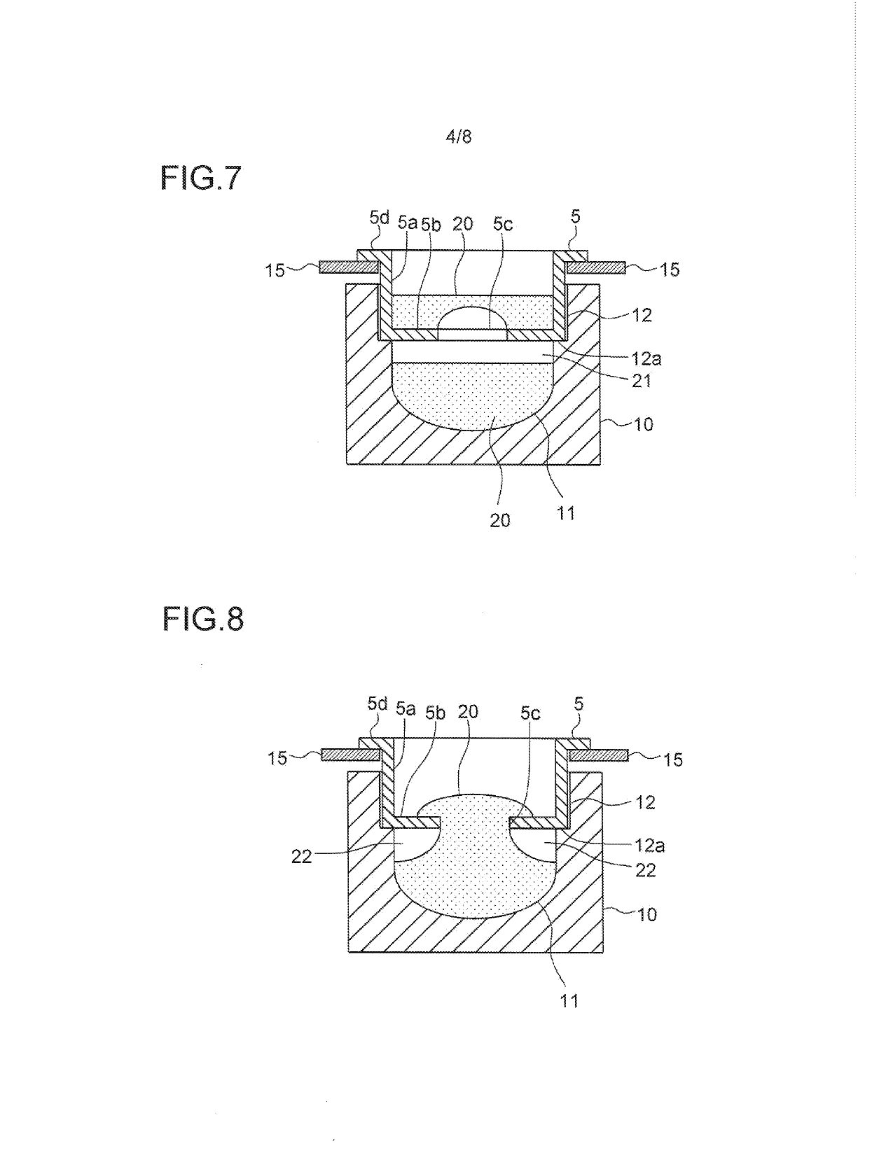

If the liquid resin 20 is poured after the cap 5 is inserted into the enlarged-diameter portion 12 as shown in FIG. 6, the following problem may arise. That is, there may be a case where surface tension of the liquid resin 20 causes the liquid resin 20 to cover the window portion 5c as shown in FIG. 7, and as a result, an air layer 21 is formed between the ceiling wall 5b and such part of the liquid resin 20 as is already in the concave portion 11. In such a case, the air layer 21 prevents the optical member 6 from being fixed to the ceiling wall 5b, and this causes reduction in yield of the optical member 6. It is possible to reduce the risk of forming the air layer 21 by reducing the diameter of a nozzle through which the liquid resin 20 is poured in to be smaller than the diameter of the window portion 5c, but then, the nozzle with the smaller diameter is more liable to be clogged, and this affects to increase the man-hours of processes.

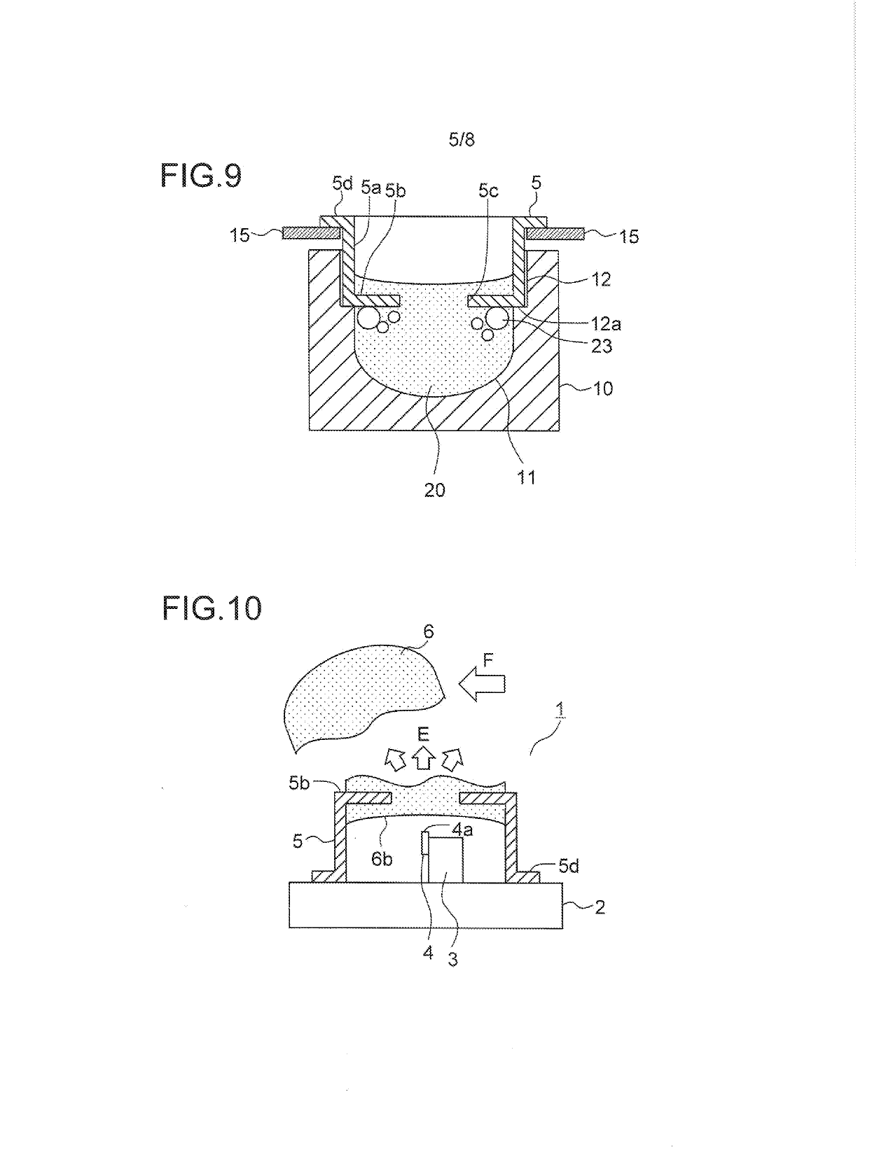

In a case where the liquid resin 20 is poured downward from the window portion 5c to prevent formation of the air layer 21, an air pool 22 may be formed under a portion around the window portion 5c as shown in FIG. 8. In such a case, air bubbles 23 remain in the optical member 6 after the liquid resin 20 cures as shown in FIG. 9, and this causes reduction in yield of the optical member 6.

Thus, as shown in FIGS. 3 to 5, by inserting the cap 5 into the enlarged-diameter portion 12 after pouring the liquid resin 20 into the mold 10 to a height above the bottom surface 12a of the enlarged-diameter portion 12, it is possible to improve the yield of the optical member 6.

In the semiconductor laser device 1 described above, since the optical member 6 holds the ceiling wall 5b of the cap 5, the optical member 6 is firmly fixed, it is possible to prevent the optical member 6 from coming off due to reduction in adhesive strength, an external force applied thereto, etc. Here, the optical member 6 is in contact with the inner surface of the peripheral wall 5a of the cap 5, it is possible to fix the optical member 6 more firmly.

As shown in FIG. 10, if a large external force F is applied to the optical member 6, an upper portion of the optical member 6 may be broken and come off. In such a case, part of the optical member 6 remains filling the window portion 5c, and causes laser light to be emitted through a broken surface in a scattered manner as indicated by arrows E. This helps prevent risk of emission of laser light into air directly from the emission region 4a.

According to the present embodiment, the transparent optical member 6 that fills the window portion 5c of the cap 5 holds the ceiling wall 5b of the cap 5, and the light incidence surface 6b of the optical member 6 is formed by natural flow of the liquid resin 20. Thereby, it is possible to prevent the optical member 6 from coming off and to form the optical member 6 by means of a simple molding apparatus. Thus, it is possible to improve safety and reduce cost of the semiconductor laser device 1.

Furthermore, since the optical member 6 is formed of a thermosetting resin, it is possible to form the optical member 6 easily by pouring the liquid resin 20 into the single mold 10 and thermally curing the liquid resin 20.

If the optical member 6 contains a scattering material such as silica, it is possible to improve operational safety of the semiconductor laser device 1 with respect to retina.

Furthermore, the cap 5 is inserted into the enlarged-diameter portion 12 after the liquid resin 20 is poured into the mold 10 to fill the concave portion 11 and to reach a height above the bottom surface 12a of the enlarged-diameter portion 12, and then the liquid resin 20 that has flown naturally through the window portion 5c onto the inner surface of the ceiling wall 5b is cured. Thereby, it is possible to easily form the optical member 6 capable of being prevented from coming off from the cap 5. It is also possible to form the optical member 6 avoiding generation of the air layer 21 or the air bubbles 23. Thus, it is possible to improve safety and reduce cost of the semiconductor laser device 1.

Moreover, since the hanger member 15 is provided for supporting the flange portion 5d, it is possible to easily insert/release the cap 5 with respect to the enlarged-diameter portion 12 of the mold 10.

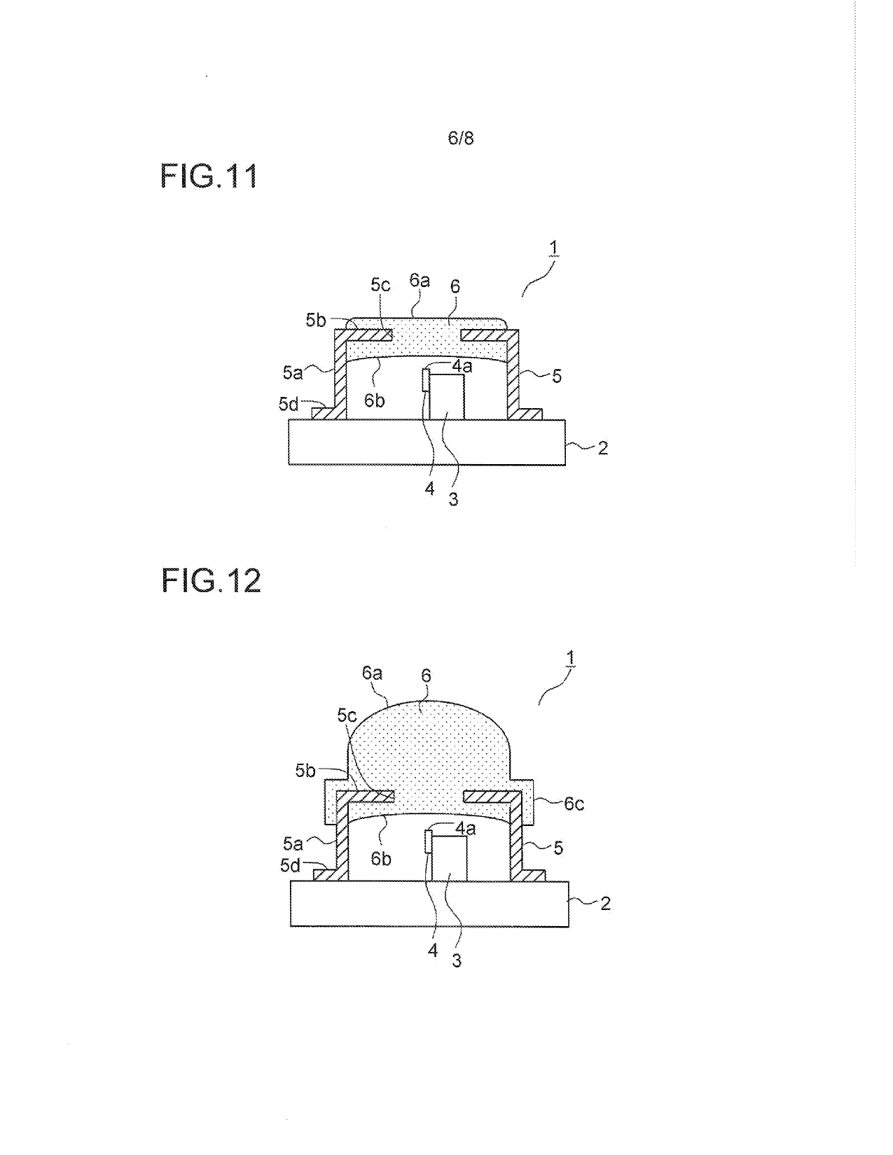

FIG. 11 shows a front sectional view of a semiconductor laser device 1 according to a second embodiment. For convenience of description, such portions as find their counterparts in the first embodiment illustrated in FIGS. 1 to 5 referred to above are denoted by common reference signs. In the present embodiment, an optical member 6 is shaped differently from the optical member 6 of the first embodiment. Other portions are the same as those of the first embodiment.

The optical member 6 has a flat light emission surface 6a, and an inside of the cap 5 is hermetically sealed. Thereby, laser light emitted from the emission region 4a of the semiconductor laser element 4 is emitted out of the semiconductor laser device 1 without being converged.

With this configuration, too, it is possible to obtain the same advantage as with the first embodiment. It is also possible to obtain the same advantage with an optical member 6 having a concave light emission surface 6a.

Next, FIG. 12 shows a front sectional view of a semiconductor laser device 1 according to a third embodiment. For convenience of description, such portions as find their counterparts in the first embodiment illustrated in FIGS. 1 to 5 referred to above are denoted by common reference signs. In the present embodiment, an optical member 6 is shaped differently from the optical member 6 of the first embodiment. Other portions are the same as those of the first embodiment.

The optical member 6 has an extension portion 6c that is formed to extend continuously from over the ceiling wall 5b of the cap 5 to over an outer surface of the peripheral wall 5a. Further, the optical member 6 is formed in contact with the inner surface of the peripheral wall 5a of the cap 5. Thereby, the ceiling wall 5b and the peripheral wall 5a of the cap 5 are held by the optical member 6.

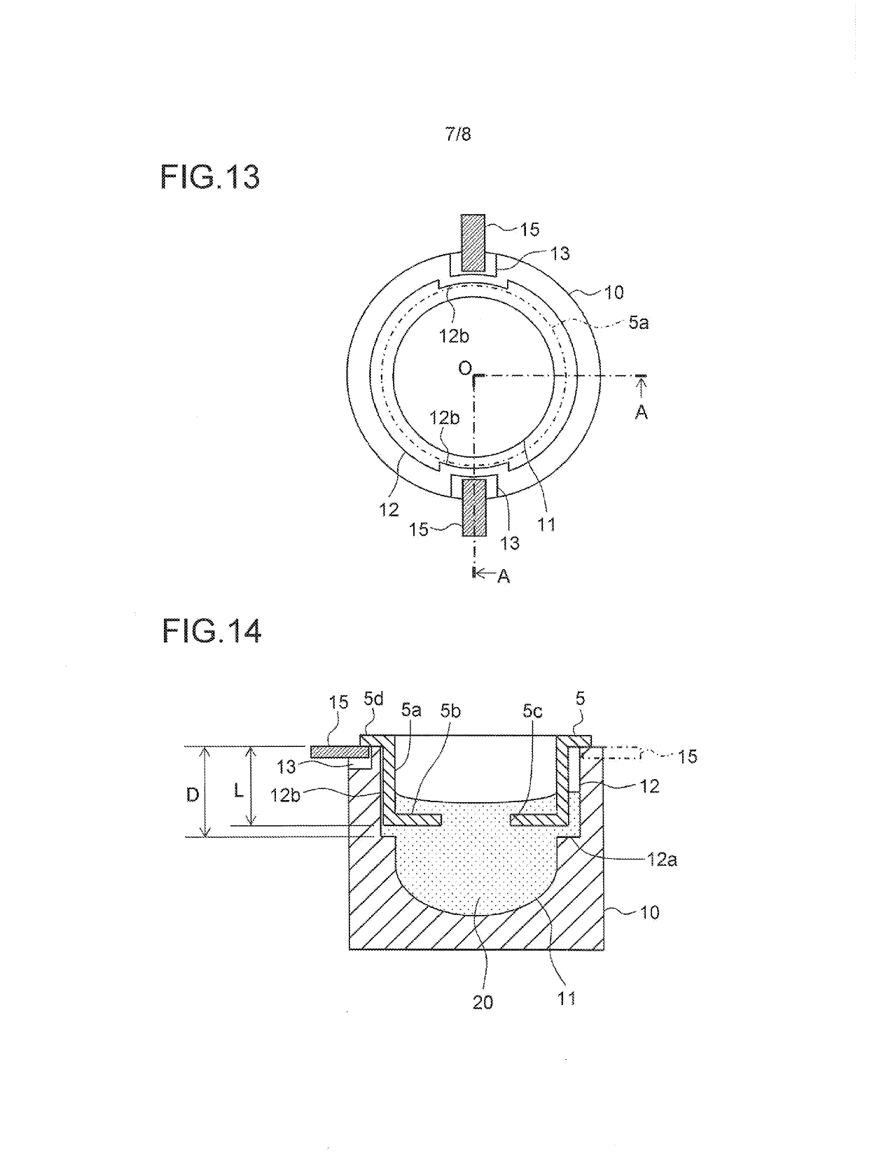

FIG. 13 shows a top view of the mold 10 of the optical member 6. FIG. 14 is a sectional view taken along line AOA of FIG. 13, and shows a state when the optical member 6 is molded by means of the mold 10. On the enlarged-diameter portion 12 of the mold 10, there are provided a plurality of inwardly-projecting projection portions 12b. The peripheral wall 5a of the cap 5 fits against inner surfaces of the projection portions 12b, and spaces equivalent to a thickness of the extension portion 6c in its diameter direction are formed between an inner surface of the enlarged-diameter portion 12 and the peripheral wall 5a between the projection portions 12b.

At an upper end portion of each of the projection portions 12b, there is formed a groove portion 13 that is open on an outer peripheral side. Furthermore, the distance L between the upper surface (which appears to be a lower surface in FIG. 14) of the ceiling wall 5b of the cap 5 and the upper surface (which appears to be a lower surface in FIG. 14) of the flange portion 5d is smaller than the depth D of the enlarged-diameter portion 12. Thus, when the flange portion 5d supported by the hanger member 15 is lowered and placed on the upper surface of the mold 10, there is formed a space equivalent to a thickness of the extension portion 6c in its axial direction, between the ceiling wall 5b and the bottom surface 12a of the enlarged-diameter portion 12. At this time, the hanger member 15 is located within the groove portion 13, making it easy to insert/release the cap 5 with respect to the enlarged-diameter portion 12.

The liquid resin 20 naturally flows on the inner surface of the ceiling wall 5b to reach the inner surface of the peripheral wall 5a and covers an upper portion of the outer surface of the peripheral wall 5a. Then, the liquid resin 20 is cured to form the resin optical member 6 that holds the ceiling wall 5b and the peripheral wall 5a of the cap 5.

According to the present embodiment, it is possible to achieve the same advantage as the first embodiment. Furthermore, since the optical member 6 holds the peripheral wall 5a of the cap 5 by the provision of the extension portion 6c, it is possible to fit the optical member 6 more firmly with respect to the cap 5. Therefore, safety of the semiconductor laser device 1 can be further improved. The semiconductor laser device 1 according to the second embodiment may be provided with the above-described extension portion 6c.

In the first to third embodiments, the optical member 6 is formed of a thermosetting resin, but instead of the thermosetting resin, the optical member 6 may be formed of an ultraviolet setting resin.

The present invention is applicable to semiconductor laser devices provided with an optical member such as a lens.

### LIST OF REFERENCE SIGNS

1 semiconductor laser device
2 stem
3 submount
4 semiconductor laser element
4a emission region
5 cap
5a peripheral wall
5b ceiling wall
5c window portion
5d flange portion
6 optical member
6a light emission surface
6b light incidence surface
6c extension portion
10 mold
11 concave portion
12 enlarged-diameter portion
12a bottom surface
12b projection portion
13 groove portion
15 hanger member
20 liquid resin
21 air layer
22 air pocket
23 air bubble

1. A semiconductor laser device, comprising:
a semiconductor laser element that emits laser light from an emission region thereof;
a cap having a peripheral wall and a ceiling wall that cover the semiconductor laser element, and having a window portion formed in the ceiling wall to face the emission region; and
a transparent optical member that fills the window portion,
wherein
the optical member is formed by curing a liquid resin and holds the ceiling wall; and
a light incidence surface of the optical member faces the emission region and is formed by natural flow of the liquid resin.

2. The semiconductor laser device according to claim 1, wherein the optical member is formed of one of a thermosetting resin and an ultraviolet setting resin.

3. The semiconductor laser device according to claim 1, wherein the optical member contains a scattering material.

4. A method for producing a semiconductor laser device comprising a
semiconductor laser element that emits laser light from an emission region thereof, a
cap having a peripheral wall and a ceiling wall that cover the semiconductor laser element, and having a window portion formed in the ceiling wall to face the emission region, and a transparent optical member that fills the window portion,
wherein
a mold is provided including a concave portion for forming a light emission surface of the optical member, and an enlarged-diameter portion that is formed at an open end of the concave portion to have a larger diameter than the concave portion, and in which the cap is to be fitted; and
a liquid resin is poured into the mold to fill the concave portion and to a height above a bottom surface of the enlarged-diameter portion, and thereafter, the cap is inserted into the enlarged-diameter portion with the ceiling wall facing downward and the liquid resin flows into the cap through the window portion and naturally flows on an inner surface of the ceiling wall, and then the liquid resin is cured, and thereby the optical member that holds the ceiling wall is formed.

5. The method for producing a semiconductor laser device according to claim 4,
wherein
the cap has a flange portion projecting outward from an end portion thereof opposite to the ceiling wall; and
a hanger member is provided for supporting the flange portion in inserting and releasing the cap with respect to the enlarged-diameter portion.

6. The semiconductor laser device according to claim 1,
wherein
the optical member has an extension portion extending continuously from over the ceiling wall to over an outer surface of the peripheral wall and contacts an inner surface of the peripheral wall, such that the peripheral wall is held by the optical member.
